(19) United States
(12) Patent Application Publication
(10) Pub. No.: US 2016/0093687 A1
(43) Pub. Date: Mar. 31, 2016

(54) CAPACITOR STRUCTURE AND FABRICATING METHOD THEREOF

(71) Applicant: UNITED MICROELECTRONICS CORPORATION, HSINCHU (TW)

(72) Inventors: Chien-Li Kuo, Hsinchu (TW); Kuei-Sheng WU, Miaoli County (TW); Ju-Bao ZHANG, Singapore (SG); Rui-Huang CHENG, New Taipei City (TW); Xing-Hua ZHANG, Singapore (SG); Hong LIAO, Singapore (SG)

(21) Appl. No.: 14/964,595

(22) Filed: Dec. 10, 2015

Related U.S. Application Data
(62) Division of application No. 13/605,983, filed on Sep. 6, 2012.

(51) Int. Cl. H01L 49/02

(52) U.S. Cl. CPC H01L 28/75

(57) ABSTRACT

The present invention provides a method for fabricating a capacitor structure, including the steps of: providing a substrate; forming a first conductive structure and a dielectric structure over the substrate, wherein the first conductive structure is enclosed by the dielectric structure; forming a first trench in the dielectric structure, so that a first surface of the first conductive structure is exposed through the first trench; forming a first capacitor electrode and a capacitor dielectric layer on a bottom and a sidewall of the first trench and on a top surface of the dielectric structure, so that the first capacitor electrode is electrically contacted with the first surface of the first conductive structure; and removing the first capacitor electrode and the capacitor dielectric layer on the top surface of the dielectric structure; forming a second capacitor electrode on a surface of the capacitor dielectric layer. A capacitor structure is also provided.

### FIELD OF THE INVENTION

The present invention relates to a capacitor structure, and more particularly to a capacitor structure manufactured by a semiconductor fabricating process. The present invention also relates to a method of fabricating the capacitor structure.

### BACKGROUND OF THE INVENTION

An integrated circuit is an electronic circuit manufactured by a semiconductor fabricating process. In the integrated circuit, a large number of electronic components are formed on a semiconductor substrate. For example, a MOS transistor and a capacitor are widely-used electronic components.

Taking a metal-insulator-metal (MIM) capacitor for example, FIG. 1 is a schematic cross-sectional view illustrating a conventional MIM capacitor structure. The MIM capacitor structure is formed between multiple layers of metal conductor lines. As shown in FIG. 1, the MIM capacitor comprises a first capacitor electrode 11, a capacitor dielectric layer 12, and a second capacitor electrode 13. The first capacitor electrode 11, the capacitor dielectric layer 12 and the second capacitor electrode 13 are disposed over a substrate 1. The MIM capacitor structure may be electrically connected with the external component through a contact hole 14 and a plurality of metal lines 15. However, the MIM capacitor has insufficient capacitance value per unit area.

Therefore, there is a need of providing a capacitor with increased capacitance value in order to eliminate the above drawbacks.

### SUMMARY OF THE INVENTION

In accordance with an aspect, the present invention provides a capacitor structure disposed over a substrate. The capacitor structure includes a first conductive structure, a dielectric structure, a first capacitor electrode, a capacitor dielectric layer, and a second capacitor electrode. The first conductive structure is disposed over the substrate. The dielectric structure is disposed over the substrate and partially enclosing the first conductive structure. The dielectric structure has a trench. A first surface of the first conductive structure is exposed through the trench of the dielectric structure. The first capacitor electrode is disposed on a bottom and a sidewall of the trench. The first capacitor electrode is electrically contacted with the first surface of the first conductive structure. The capacitor dielectric layer is disposed on a surface of the first capacitor electrode. The second capacitor electrode is disposed on a surface of the capacitor dielectric layer and filled in the trench.

In an embodiment, the substrate is a silicon interposer.

In an embodiment, the first conductive structure is a damascene conductor structure.

In an embodiment, the dielectric structure includes an inter-layer dielectric layer, a first etch stop layer, a first inter-metal dielectric layer, a second etch stop layer, a second inter-metal dielectric layer, a third etch stop layer, and a third inter-metal dielectric layer. The inter-layer dielectric layer is formed over the substrate. The first etch stop layer is formed on the inter-layer dielectric layer. The first inter-metal dielectric layer is formed on the first etch stop layer. The second etch stop layer is formed on the first inter-metal dielectric layer. The second inter-metal dielectric layer is formed on the second etch stop layer. The third etch stop layer is formed on the second inter-metal dielectric layer. The third inter-metal dielectric layer is formed on the third etch stop layer. The trench runs through the third inter-metal dielectric layer, the third etch stop layer, the second inter-metal dielectric layer and the second etch stop layer, so that the first surface of the first conductive structure is exposed through the trench of the dielectric structure.

In an embodiment, the dielectric structure includes an inter-layer dielectric layer, a first etch stop layer, a first inter-metal dielectric layer, a second etch stop layer, a second inter-metal dielectric layer, a third etch stop layer, a third inter-metal dielectric layer, a fourth etch stop layer, a fourth inter-metal dielectric layer, a fifth etch stop layer, and a fifth inter-metal dielectric layer. The inter-layer dielectric layer is formed over the substrate. The first etch stop layer is formed on the inter-layer dielectric layer. The first inter-metal dielectric layer is formed on the first etch stop layer. The second etch stop layer is formed on the first inter-metal dielectric layer. The second inter-metal dielectric layer is formed on the second etch stop layer. The third etch stop layer is formed on the second inter-metal dielectric layer. The third inter-metal dielectric layer is formed on the third etch stop layer. The fourth etch stop layer is formed on the third inter-metal dielectric layer. The fourth inter-metal dielectric layer is formed on the fourth etch stop layer. The fifth etch stop layer is formed on the fourth inter-metal dielectric layer. The fifth inter-metal dielectric layer is formed on the fifth etch stop layer. The trench runs through the fifth inter-metal dielectric layer, the fifth etch stop layer, the fourth inter-metal dielectric layer, the fourth etch stop layer, the third inter-metal dielectric layer, the third etch stop layer, the second inter-metal dielectric layer and the second etch stop layer, so that said first surface of the first conductive structure is exposed through the trench of the dielectric structure.

In an embodiment, the first capacitor electrode is a titanium/titanium nitride layer, the capacitor dielectric layer is a silicon nitride layer, and the second capacitor electrode includes a damascene metal conductor structure.

In an embodiment, the second capacitor electrode includes a copper conductor line as the damascene metal conductor structure and a barrier layer. The barrier layer is arranged between the copper conductor line and the capacitor dielectric layer.

In accordance with another aspect, the present invention provides a method for fabricating a capacitor structure. The method includes the following steps. Firstly, a substrate is provided. Then, a first conductive structure and a dielectric structure are formed over the substrate, wherein the first conductive structure is enclosed by the dielectric structure. Then, a first trench is formed in the dielectric structure, so that a first surface of the first conductive structure is exposed through the first trench. Then, a first capacitor electrode is formed on a bottom and a sidewall of the first trench, so that the first capacitor electrode is electrically contacted with the first surface of the first conductive structure. Then, a capacitor dielectric layer is formed on a surface the first capacitor electrode. Afterwards, a second capacitor electrode is formed on a surface of the capacitor dielectric layer.

In an embodiment, the substrate is a silicon interposer.

In an embodiment, the step of forming the first conductive structure and the dielectric structure includes sub-steps of forming an inter-layer dielectric layer over the substrate, forming a first etch stop layer on the inter-layer dielectric layer, forming a first inter-metal dielectric layer on the first etch stop layer, forming a second trench in the first inter-metal dielectric layer and the first etch stop layer, forming a first conductive structure in the second trench, forming a second etch stop layer on the first inter-metal dielectric layer and the first conductive structure, forming a second inter-metal dielectric layer on the second etch stop layer, forming a third etch stop layer on the second inter-metal dielectric layer, and forming a third inter-metal dielectric layer formed on the third etch stop layer.

In an embodiment, the step of forming the first trench is performed by etching the third inter-metal dielectric layer, the third etch stop layer, the second inter-metal dielectric layer and the second etch stop layer, so that the first surface of the first conductive structure is exposed through the first trench of the dielectric structure.

In an embodiment, the method further includes the following steps. A third trench is formed in the first inter-metal dielectric layer and the first etch stop layer at the same time when the second trench is formed in the first inter-metal dielectric layer and the first etch stop layer. A second conductive structure is formed in the third trench at the same time when the first conductive structure is formed in the second trench. A fourth trench is formed by etching the third inter-metal dielectric layer, the third etch stop layer, the second inter-metal dielectric layer and the second etch stop layer overlying the second conductive structure, so that a surface of the second conductive structure is exposed through the fourth trench. A barrier layer is formed in the fourth trench. A copper conductor material is filled into the fourth trench and covers a surface of the barrier layer, and then a chemical mechanical polishing process is performed to partially remove the copper conductor material and the barrier layer outside the fourth trench, thereby producing a copper damascene conductor structure.

In an embodiment, the second capacitor electrode and the copper damascene conductor structure are simultaneously formed by the same fabricating process.

In an embodiment, the second capacitor electrode and the copper damascene conductor structure are formed by different fabricating processes.

In an embodiment, the step of forming the fourth trench is performed after the step of forming the first trench.

In an embodiment, the step of forming the first trench is performed after the step of forming the fourth trench and after a filling material is filled into the fourth trench. Before performing the steps of forming the first trench and forming the second capacitor electrode inside the first trench, the filling material is removed.

In an embodiment, the step of forming the first conductive structure and the dielectric structure further includes sub-steps of forming a fourth etch stop layer on the third inter-metal dielectric layer, forming a fourth inter-metal dielectric layer on the fourth etch stop layer, forming a fifth etch stop layer on the fourth inter-metal dielectric layer, forming a fifth inter-metal dielectric layer on the fifth etch stop layer, and etching the fifth inter-metal dielectric layer, the fifth etch stop layer, the fourth inter-metal dielectric layer and the fourth etch stop layer.

In an embodiment, the first capacitor electrode is a titanium/titanium nitride layer, the capacitor dielectric layer is a silicon nitride layer, and the second capacitor electrode includes a damascene conductor structure.

In an embodiment, the second capacitor electrode is formed by steps of forming a barrier layer on the surface of the capacitor dielectric layer, filling a copper conductor material into the first trench on a surface of the barrier layer to form a damascene conductor structure, and performing a chemical mechanical polishing process to partially remove the copper conductor material and the barrier layer outside the first trench.

### BRIEF DESCRIPTION OF THE DRAWINGS

The above objectives and advantages of the present invention will become more readily apparent to those ordinarily skilled in the art after reviewing the following detailed description and accompanying drawings, in which:

FIG. 1 is a schematic cross-sectional view illustrating a conventional MIM capacitor structure;

FIGS. 2A-2F are schematic cross-sectional views illustrating a method of fabricating a capacitor according to an embodiment of the present invention; and

FIG. 3 is a schematic cross-sectional view illustrating a capacitor structure according to another embodiment of the present invention.

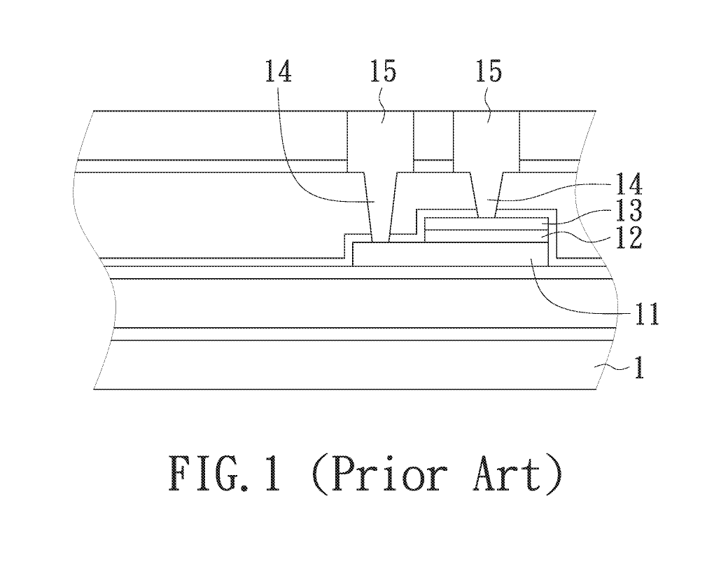

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

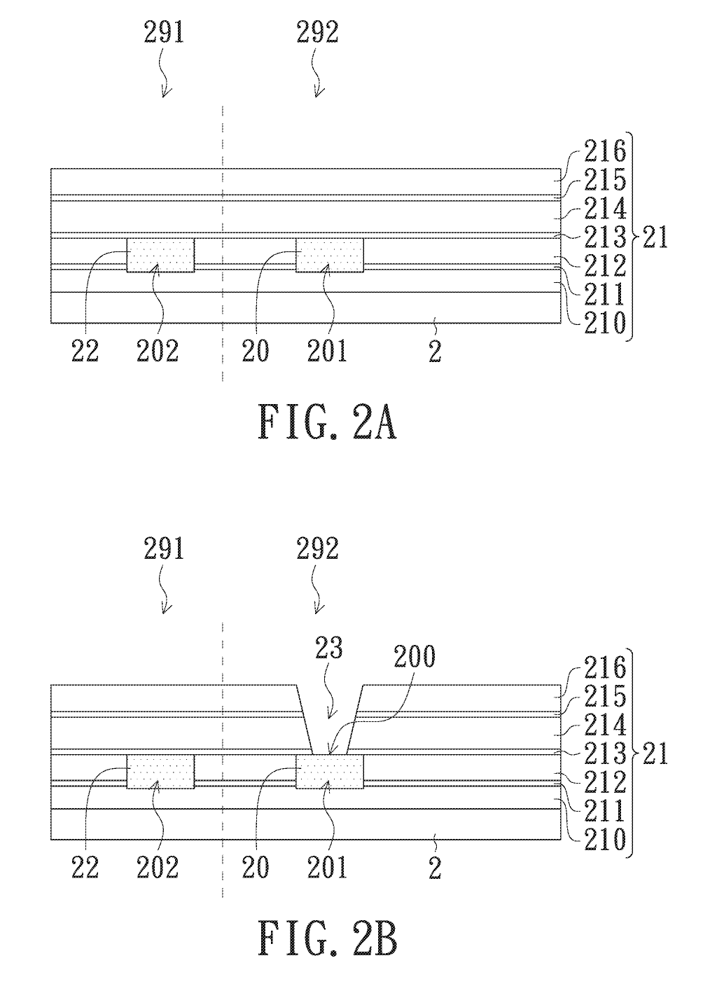

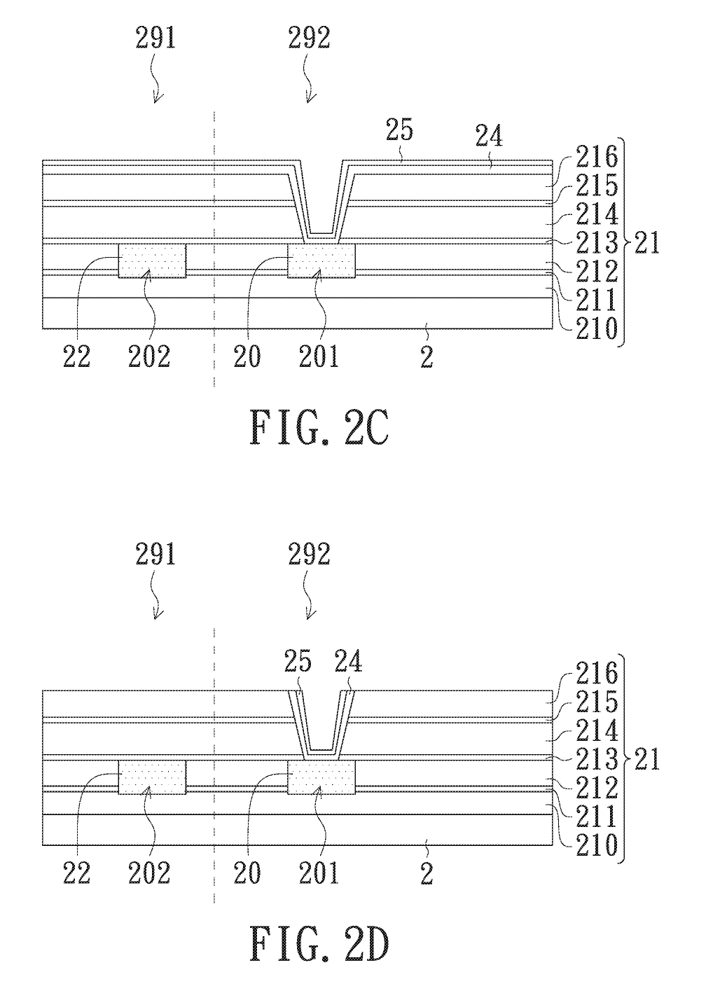

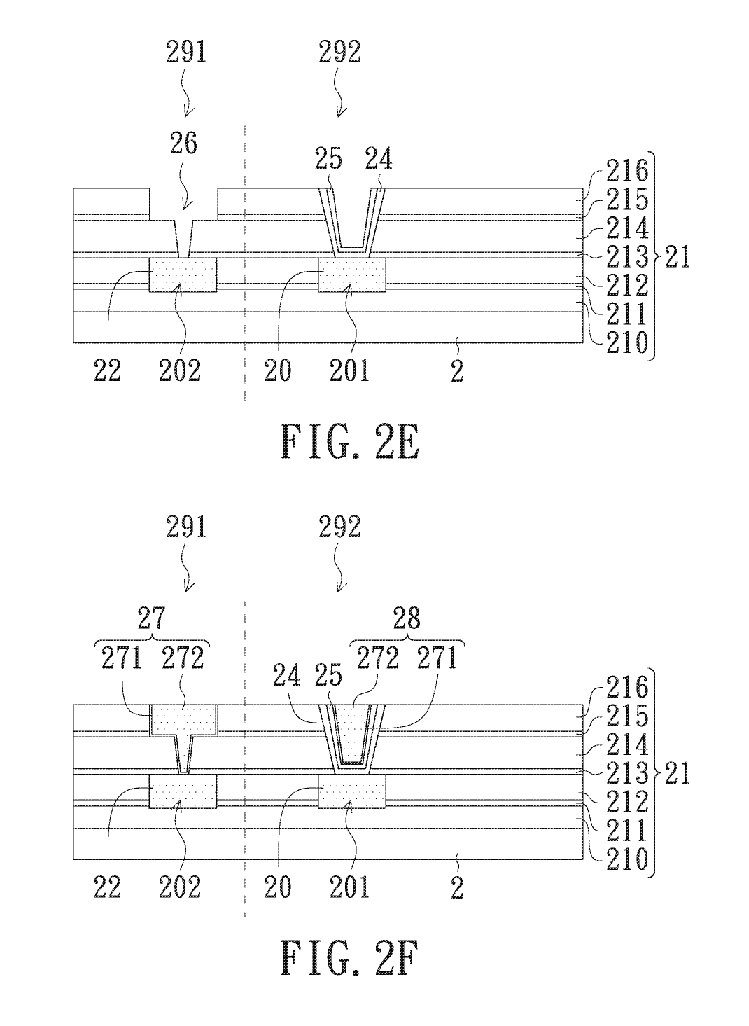

FIGS. 2A-2F are schematic cross-sectional views illustrating a method of fabricating a capacitor according to an embodiment of the present invention.

Firstly, as shown in FIG. 2A, a substrate 2 is provided. The region over the substrate 2 is divided into an interconnect region 291 and a capacitor region 292. In addition, a first conductive structure 20 and a dielectric structure 21 are formed over the substrate 2. The first conductive structure 20 is enclosed by the dielectric structure 21. In this embodiment, the first conductive structure 20 is formed by a damascene process, which comprises the following sub-steps. An inter-layer dielectric layer (ILD) 210 is firstly formed on the substrate 2. Then, a first etch stop layer 211 is formed on the inter-layer dielectric layer 210. Then, a first inter-metal dielectric layer (IMD) 212 is formed on the first etch stop layer 211. Then, a second trench 201 and a third trench 202 are formed in the first inter-metal dielectric layer 212 and the first etch stop layer 211, which are located at the capacitor region 292 and the interconnect region 291, respectively. Then, a first conductive structure 20 and a second conductive structure 22, which are damascene metal conductor structure, are formed by filling a metal conductor material into the second trench 201 and the third trench 202, respectively. Then, a second etch stop layer 213 is formed on the surfaces of the first inter-metal dielectric layer 212, the first conductive structure 20 and the second conductive structure 22. Then, a second inter-metal dielectric layer 214 is formed on the second etch stop layer 213. Then, a third etch stop layer 215 is formed on the second inter-metal dielectric layer 214. Then, a third inter-metal dielectric layer 216 is formed on the third etch stop layer 215.

Then, a metal conductor line and a capacitor structure are formed by further damascene processes. As shown in FIG. 2B, a photolithography and etching process is performed to form a first trench 23 in the dielectric structure 21. The first trench 23 is formed by etching the third inter-metal dielectric layer 216, the third etch stop layer 215, the second inter-metal dielectric layer 214 and the second etch stop layer 213 overlying the first conductive structure 20. Consequently, a first surface 200 of the first conductive structure 20 is exposed through the first trench 23.

Then, as shown in FIG. 2C, a first capacitor electrode 24 and a capacitor dielectric layer 25 are sequentially formed on a bottom and a sidewall of the first trench 23. Then, a chemical mechanical polishing (CMP) process is performed to partially remove the first capacitor electrode 24 and the capacitor dielectric layer 25. The resulting structure of the semi-finished capacitor is shown in FIG. 2D.

Then, as shown in FIG. 2E, another photolithography and etching process is performed to form a fourth trench 26 in the dielectric structure 21. The fourth trench 26 is formed by etching the third inter-metal dielectric layer 216, the third etch stop layer 215, the second inter-metal dielectric layer 214 and the second etch stop layer 213 overlying the second conductive structure 22. Consequently, a first surface of the second conductive structure 22 is exposed through the fourth trench 26.

Then, a barrier layer 271 is simultaneously formed inside the first trench 23, in which the first capacitor electrode 24 and a capacitor dielectric layer 25 have been formed, and the fourth trench 26, and a metal conductor material, e.g. copper, is filled into the first trench 23 and the fourth trench 26, covering the surface of the barrier layer 271. After a chemical mechanical polishing (CMP) process is performed to partially remove the copper conductor material 272 and the barrier layer 271 outside the trenches, i.e. the top surfaces of the copper conductor line 272 and the barrier layer 271 are made substantially at the same level as the surface of the third inter-metal dielectric layer 216., a second capacitor electrode 28, which is a damascene metal conductor structure, and a Cu damascene conductor line 27 are formed in the capacitor region 292 and the interconnect region 291 over the first conductive structure 20 and the second conductive structure 22, respectively, as shown in FIG. 2F. Alternatively, the barrier layer may be omitted, and the Cu damascene conductor line 27 in the interconnect region 291 and the second capacitor electrode 28 in the capacitor structure of the capacitor region 292 may be constructed by the copper conductor material 272 itself.

Please refer to FIG. 2F again. In a case that the planar area is kept unchanged, the effective electrode area of the capacitor structure of the present invention is largely enhanced by increasing the depth of the first trench 23. Moreover, the fabricating method of the present invention may be applied to the semiconductor structure with multiple layers of metal conductor lines. The above embodiment is illustrated by referring to a semiconductor structure with two layers of metal conductor lines. Alternatively, the fabricating method of the present invention may be applied to another semiconductor structure with three or more layers of metal conductor lines in order to enhance the effective electrode area of the capacitor structure.

In the process that the step of forming the fourth trench 26 is performed after the step of forming the first trench 23, contaminants are readily retained in the first trench 23. The contaminants might be detrimental to the performance of the subsequent processes. For solving this problem, the step of forming the fourth trench 26 may be performed prior to the step of forming the first trench 23. After the fourth trench 26 is defined, a filling material (e.g. a photoresist material) is filled into the fourth trench 26, and then the step of forming the first trench 23 is performed. After the first trench 23 is formed, the filling material is removed. Then, a barrier layer 271 and a copper conductor material 272 are sequentially formed in both the first trench 23 and the fourth trench 26 with the copper conductor material 272 covering the surface of the barrier layer 271. Then, a chemical mechanical polishing (CMP) process is performed to partially remove the copper conductor material 272 and the barrier layer 271 outside the trenches, so that the top surfaces of the copper conductor material 272 and the barrier layer 271 are substantially at the same level as the surface of the third inter-metal dielectric layer 216. Meanwhile, a second capacitor electrode 28, which includes a damascene metal conductor structure, and a Cu damascene conductor line 27 are formed in the capacitor region 292 and the interconnect region 291 over the first conductive structure 20 and the second conductive structure 22, respectively. In such embodiment, the possibility of retaining the contaminants in the first trench 23 will be minimized.

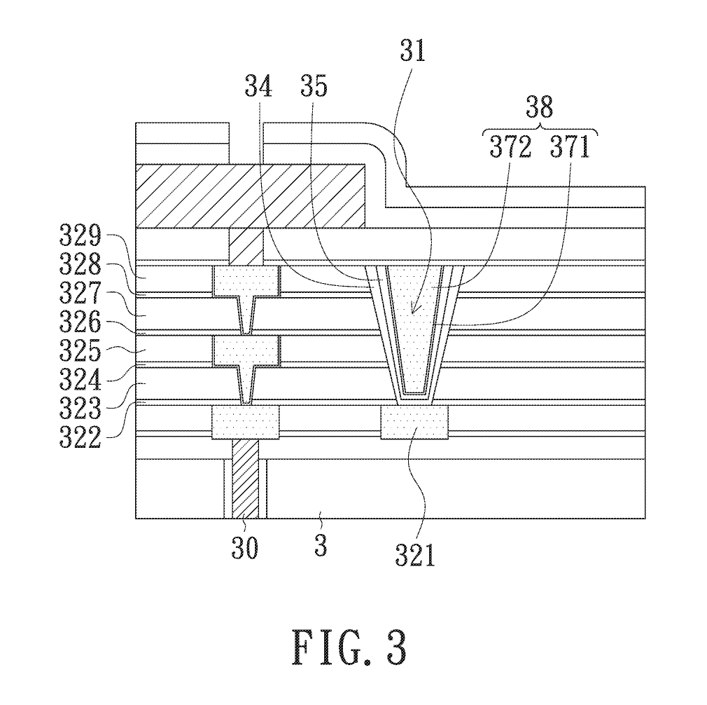

Alternatively, in some embodiments, after the first trench 23 is formed, a first capacitor electrode 24, a capacitor dielectric layer 25 and a second capacitor electrode 28 are sequentially formed in the first trench 23. Then, a chemical mechanical polishing (CMP) process is performed to flatten the surfaces of the first capacitor electrode 24, the capacitor dielectric layer 25 and the second capacitor electrode 28, so that an individual capacitor structure is produced. Then, a photolithography and etching process and a chemical mechanical polishing (CMP) process are sequentially performed to form a fourth trench 26 and a Cu damascene conductor structure 27. In such embodiments, the possibility of retaining the contaminants in the first trench 23 will be minimized. It is noted that numerous modifications and alterations may be made while retaining the teachings of the invention. FIG. 3 is a schematic cross-sectional view illustrating a capacitor structure according to another embodiment of the present invention. As shown in FIG. 3, the substrate 3 is a silicon interposer with a through-silicon via (TSV) conductor 30. Moreover, three layers of metal conductor lines are disposed over the substrate 3. In this embodiment, the capacitor structure is formed in a trench 31. The trench 31 runs through a fifth inter-metal dielectric layer 329, a fifth etch stop layer 328, a fourth inter-metal dielectric layer 327, a fourth etch stop layer 326, a third inter-metal dielectric layer 325, a third etch stop layer 324, a second inter-metal dielectric layer 323 and a second etch stop layer 322. Consequently, a surface of a first conductive structure 321, which is a damascene metal conductor structure, is exposed through the trench 31. The capacitor structure in the trench 31 comprises a first capacitor electrode 34, a capacitor dielectric layer 35 and a second capacitor electrode 38. The second capacitor electrode 38 is composed of a barrier layer 371 and a copper damascene conductor structure 372. In one embodiment, the first capacitor electrode 34 is a titanium/titanium nitride (Ti/TiN) layer. The capacitor dielectric layer 35 is a silicon nitride layer, a silicon oxide layer, a silicon oxynitride layer, a silicon carbide, a high-k dielectric layer, or their combination. The high-k dielectric layer includes rare earth metal oxide, such as hafnium oxide (HfO₂), hafnium silicon oxide (HfSiO₄), hafnium silicon oxynitride (HfSiON), aluminum oxide (Al₂O₃), lanthanum oxide (La₂O₃), lanthanum aluminum oxide (LaAlO), tantalum oxide (Ta₂O₅), zirconium oxide (ZrO₂), zirconium silicon oxide (ZrSiO₄), hafnium zirconium oxide (HfZrO), strontium bismuth tantalate (SrBi₂Ta₂O₉, SBT), lead zirconate titanate (PbZrₓTi₁₋ₓO₃, PZT) or barium strontium titanate (BaₓSr₁₋ₓTiO₃, BST), but is not limited thereto. Moreover, the barrier layer 371 of the second capacitor electrode 38 is a tantalum/tantalum nitride (Ta/TaN) layer. In this embodiment, the silicon interposer comprises a silicon substrate and a 65 μm-wide or 55 μm-wide multilayered metal structure on the silicon substrate. There is no active component formed on the silicon interposer. The silicon interposer is usually adopted for integrating multiple chips by a multi-chip packaging technology.

From the above description, the capacitor structure and the fabricating method of the present invention are effective to increase the capacitance value per unit area. The capacitor structure and the fabricating method of the present invention may be applied to various semiconductor substrates. Especially when the capacitor structure is formed on a silicon interposer with a through-silicon via conductor, the benefits are enhanced and the capacitor structure is advantageous for development of the multi-chip packaging technology. That is, the silicon interposer plays an important role in interconnection between multiple chips. In comparison with the wire between the general integrated circuit package and the circuit board, the size of the wire on the silicon interposer may be further reduced. Consequently, the efficiency of signal transmission between chips is enhanced. Moreover, through the through-silicon via (TSV) conductor, many silicon interposers may be vertically stacked on each other.

Consequently, the device integration on the equivalent area is increased. Moreover, since the through-silicon via (TSV) conductor is not directly penetrated through the active regions of the chips, the risk of resulting in systematic breakdown will be minimized.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a capacitor structure, the method comprising steps of:
providing a substrate;
forming a first conductive structure and a dielectric structure over the substrate, wherein the first conductive structure is enclosed by the dielectric structure;
forming a first trench in the dielectric structure, so that a first surface of the first conductive structure is exposed through the first trench;
forming a first capacitor electrode and a capacitor dielectric layer on a bottom and a sidewall of the first trench and on a top surface of the dielectric structure, so that the first capacitor electrode is electrically contacted with the first surface of the first conductive structure; and
removing the first capacitor electrode and the capacitor dielectric layer on the top surface of the dielectric structure;
forming a second capacitor electrode on a surface of the capacitor dielectric layer.

2. The method according to claim 1, wherein the substrate is a silicon interposer.

3. The method according to claim 1, wherein the step of forming the first conductive structure and the dielectric structure comprises sub-steps of:
forming an inter-layer dielectric layer over the substrate;
forming a first etch stop layer on the inter-layer dielectric layer;
forming a first inter-metal dielectric layer on the first etch stop layer;
forming a second trench in the first inter-metal dielectric layer and the first etch stop layer;
forming the first conductive structure in the second trench;
forming a second etch stop layer on the first inter-metal dielectric layer and the first conductive structure;
forming a second inter-metal dielectric layer on the second etch stop layer;
forming a third etch stop layer on the second inter-metal dielectric layer; and
forming a third inter-metal dielectric layer on the third etch stop layer.

4. The method according to claim 3, wherein the step of forming the first trench is performed by etching the third inter-metal dielectric layer, the third etch stop layer, the second inter-metal dielectric layer and the second etch stop layer, so that the first surface of the first conductive structure is exposed through the first trench of the dielectric structure.

5. The method according to claim 3, further comprising steps of:
forming a third trench in the first inter-metal dielectric layer and the first etch stop layer at the same time when the second trench is formed in the first inter-metal dielectric layer and the first etch stop layer;
forming a second conductive structure in the third trench at the same time when the first conductive structure is formed in the second trench;
forming a fourth trench by etching the third inter-metal dielectric layer, the third etch stop layer, the second inter-metal dielectric layer and the second etch stop layer overlying the second conductive structure, so that a surface of the second conductive structure is exposed through the fourth trench;
forming a barrier layer in the fourth trench;
filling a copper conductor material into the fourth trench on a surface of the barrier layer; and
performing a chemical mechanical polishing process to partially remove the copper conductor material and the barrier layer outside the fourth trench, thereby producing a copper damascene conductor structure.

6. The method according to claim 5, wherein the second capacitor electrode and the copper damascene conductor structure are simultaneously formed by the same fabricating process.

7. The method according to claim 5, wherein the second capacitor electrode and the copper damascene conductor structure are formed by different fabricating processes.

8. The method according to claim 5, wherein the step of forming the fourth trench is performed after the step of forming the first trench.

9. The method according to claim 5, wherein the step of forming the first trench is performed after the step of forming the fourth trench and a filling material is filled into the fourth trench, and before forming the second capacitor electrode, the filling material is removed.

10. The method according to claim 5, wherein the step of forming the first conductive structure and the dielectric structure further comprises sub-steps of:
forming a fourth etch stop layer on the third inter-metal dielectric layer;
forming a fourth inter-metal dielectric layer on the fourth etch stop layer;
forming a fifth etch stop layer on the fourth inter-metal dielectric layer;
forming a fifth inter-metal dielectric layer on the fifth etch stop layer; and
etching the fifth inter-metal dielectric layer, the fifth etch stop layer, the fourth inter-metal dielectric layer and the fourth etch stop layer.

11. The method according to claim 1, wherein the first capacitor electrode is a titanium/titanium nitride layer, the capacitor dielectric layer is a silicon nitride layer, and the second capacitor electrode includes a damascene metal conductor structure.

12. The method according to claim 11, wherein the second capacitor electrode is formed by steps of:
forming a barrier layer on the surface of the capacitor dielectric layer;
filling a copper conductor material into the first trench on a surface of the barrier layer to form the damascene metal conductor structure; and
performing a chemical mechanical polishing process to partially remove the copper conductor material and the barrier layer outside the first trench.
